(19) United States
(12) Patent Application Publication
(10) Pub. No.: US 2025/0079338 A1
(43) Pub. Date: Mar. 6, 2025

(54) SEMICONDUCTOR PACKAGE

(71) Applicant: Samsung Electronics Co., Ltd., Suwon-si (KR)

(72) Inventors: Sunggu KANG, Suwon-si (KR); Youngjoon KOH, Suwon-si (KR); Jae Choon KIM, Suwon-si (KR); Sung-Ho MUN, Suwon-si (KR); Hwanjoo PARK, Suwon-si (KR)

(73) Assignee: Samsung Electronics Co., Ltd., Suwon-si (KR)

(21) Appl. No.: 18/752,055

(22) Filed: Jun. 24, 2024

(30) Foreign Application Priority Data
Sep. 1, 2023 (KR) 10-2023-0116395

(51) Int. Cl. H01L 23/00; H01L 23/24; H01L 23/28; H01L 23/36; H01L 23/498; H01L 23/538; H01L 25/065; H01L 25/16

(52) U.S. Cl. CPC H01L 23/562; H01L 23/24; H01L 23/36; H01L 23/5385; H01L 25/0655; H01L 25/162; H01L 23/28; H01L 23/49816; H01L 24/16; H01L 2224/16225

(57) ABSTRACT

A semiconductor package may comrpise a substrate, a chip structure on the substrate, a passive element structure in the substrate and including a passive element, and a stiffening structure at least partially overlapping the passive element structure. A top surface of the passive element may be below a top surface of the substrate.

### CROSS-REFERENCE TO RELATED APPLICATION

This U.S. nonprovisional application claims priority under 35 U.S.C § 119 to Korean Patent Application No. 10-2023-0116395 filed on Sep. 1, 2023 in the Korean Intellectual Property Office, the disclosure of which is hereby incorporated by reference in its entirety.

### BACKGROUND

Example embodiments of some inventive concepts relate to a semiconductor package, for example to a semiconductor package including a passive element structure.

A semiconductor package is provided to implement an integrated circuit chip to qualify for use in electronic products. Conventionally, a semiconductor package is configured such that a semiconductor chip is mounted on a printed circuit board (PCB) and bonding wires or bumps are used to electrically connect the semiconductor chip to the printed circuit board. With recent developments of electronic industry, semiconductor packages are variously developed to reach goals of, for example, compact size, small weight, and/or low manufacturing cost. In addition, many kinds of semiconductor packages have been developed with the expansion of application fields such as high-capacity mass storage devices. For example, thermal characteristics of semiconductor packages have become of increasing importance because of power consumption increases resulting from high speed and capacity.

### SUMMARY

Some example embodiments of inventive concepts relate to a semiconductor package whose thermal radiation is improved.

Aspects of inventive concepts are not limited to the mentioned above, and other aspects which have not been mentioned above will be clearly understood to those ordinarily skilled in the art from the following description.

According to some example embodiments of inventive concept, a semiconductor package may comprise: a substrate; a chip structure on the substrate; a passive element structure in the substrate and including a passive element; and a stiffening structure at least partially overlapping the passive element structure. A top surface of the passive element may be below a top surface of the substrate.

According to some example embodiments of inventive concepts, a semiconductor package may comprise: a substrate; a chip structure on the substrate; a passive element structure in the substrate, the passive element structure and including a passive element and a resilient insulator on the passive element; and a stiffening structure at least partially overlapping the passive element structure. The passive element structure may be in a cavity defined by the substrate.

According to some example embodiments of inventive concepts, a semiconductor package may comprise: a substrate; a chip structure on the substrate; a passive element structure in a cavity defined by the substrate, wherein the passive element structure includes a passive element and a resilient insulator on the passive element; and a stiffening structure at least partially overlapping the passive element structure. A top surface of the passive element may be below a top surface of the substrate. A top surface and a lateral surface of the passive element may contact the resilient insulator. An adhesive layer may be between the stiffening structure and the passive element structure.

### BRIEF DESCRIPTION OF DRAWINGS

FIG. 1 illustrates a plan view showing a semiconductor package according to example embodiments of some inventive concepts.

FIG. 2 illustrates a cross-sectional view showing a semiconductor package according to example embodiments of some inventive concepts.

FIG. 3 illustrates a cross-sectional view showing a semiconductor package according to example embodiments of some inventive concepts.

FIGS. 4, 5, and 6 illustrate cross-sectional views showing a method of fabricating a semiconductor package according to example embodiments of some inventive concepts.

### DETAILED DESCRIPTION OF THE DRAWINGS

Some example embodiments of the inventive concepts will now be described in detail with reference to the accompanying drawings to aid in clearly explaining some inventive concepts.

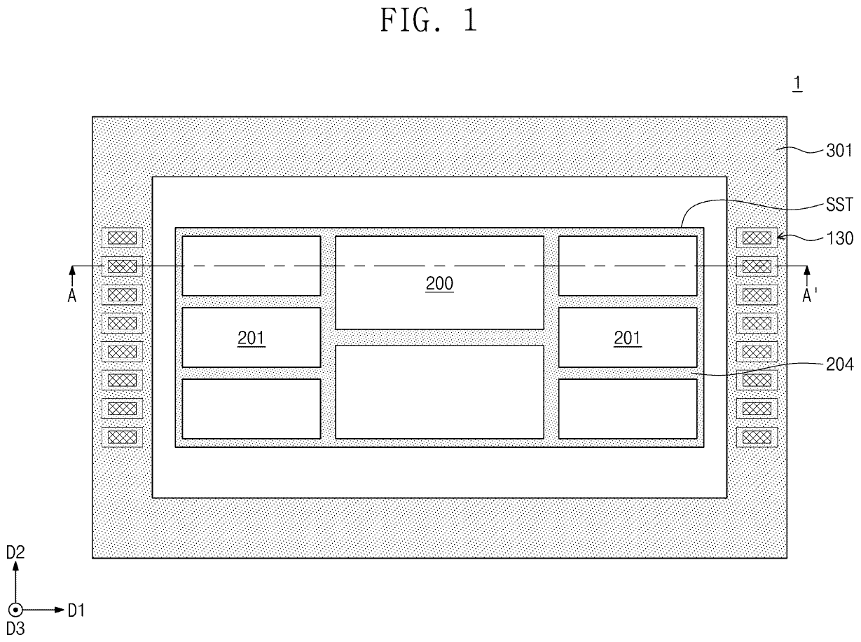

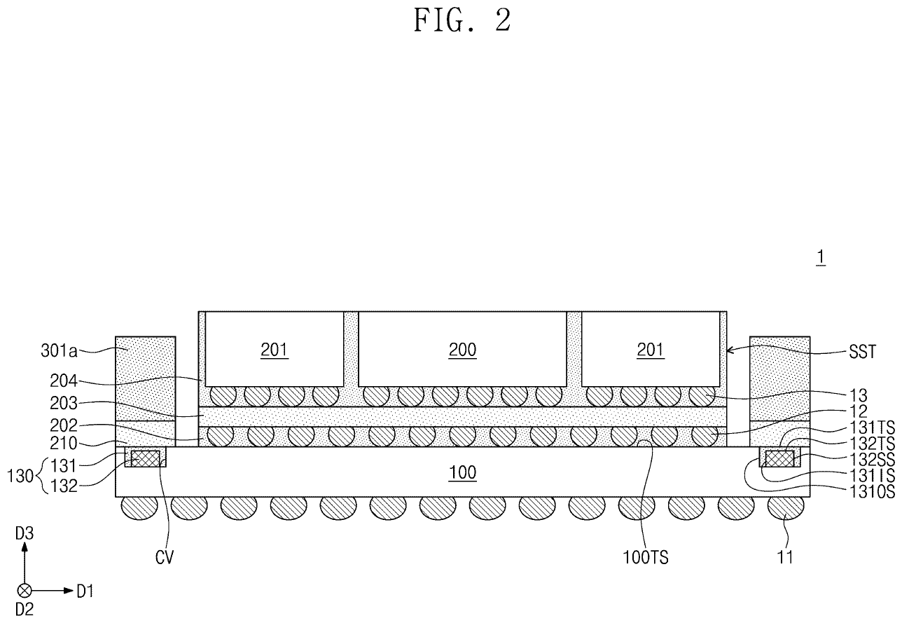

FIG. 1 illustrates a plan view showing a semiconductor package according to example embodiments of some inventive concepts. FIG. 2 illustrates a cross-sectional view showing a semiconductor package according to example embodiments of some inventive concepts. FIG. 2 shows a cross-sectional view taken along line A-A′ of FIG. 1.

Referring to FIGS. 1 and 2, a semiconductor package 1 may include an external terminal 11, a substrate 100 on the external terminal 11, a passive element structure 130 in the substrate 100, a chip structure SST on the substrate 100, a stiffening structure 301a on the substrate 100, and an adhesive layer 210 interposed between the stiffening structure 301a and the passive element structure 130.

The substrate 100 may have a plate shape that extends along a plane elongated in a first direction D1 and a second direction D2. The first direction D1 and the second direction D2 may intersect each other. For example, the first direction D1 and the second direction D2 may be horizontal directions that are orthogonal to each other. A third direction D3 may be perpendicular to a top surface 100TS of the substrate 100.

When viewed in plan, a plurality of passive element structures 130 may be disposed to be spaced apart from each other and to overlap each other in the second direction D2. The passive element structures 130 may be disposed spaced apart from each other on opposite sides of the chip structure SST.

When viewed in plan, the chip structure SST may be disposed between the passive element structures 130 that are spaced apart from each other in the first direction D1. The chip structure SST may have a structure in which a logic chip 200 is disposed between a plurality of semiconductor chips 201.

The external terminal 11 may be disposed below the substrate 100. The external terminal 11 may be provided in plural, and the plurality of external terminals 11 may be horizontally spaced apart from each other. The external terminals 11 may be disposed on a bottom surface of the substrate 100. The external terminal 11 may include at least one of solders, pillars, and bumps. The external terminal 11 may include, for example, a conductive metallic material. The external terminal 11 may include, for example, at least one selected from tin (Sn), lead (Pb), nickel (Ni), gold (Au), silver (Ag), copper (Cu), and aluminum (Al), or alloys thereof, but example embodiments are not limited thereto. The external terminal 11 may be coupled to an external device (not shown).

The substrate 100 may be disposed on the external terminal 11. The substrate 100 may be, for example, a redistribution substrate including a redistribution pattern. For example, the substrate 100 may include, for example, a monocrystalline silicon wafer, a silicon epitaxial layer, or a silicon-on-insulator (SOI) substrate, but example embodiments are not limited thereto. The substrate 100 may define a cavity (for example an unfilled, filled, or at least partially filled cavity) CV. The substrate 100 may define a plurality of cavities CV.

The passive element structure 130 may be disposed in the substrate 100. The passive element structure 130 may be mounted in the cavity CV of the substrate 100. The passive element structure 130 may include a passive element 132 and a resilient insulator 131 on the passive element 132.

The passive element 132 may include, for example, at least one of a capacitor, a diode, a photodiode, and a resistor, but example embodiments are not limited thereto. The passive element 132 may be electrically connected to the chip structure SST. A top surface 132TS of the passive element 132 may be, for example, located at a lower level than that of the top surface 100TS of the substrate 100, but example embodiments are not limited thereto.

The resilient insulator 131 may be disposed to surround or at least partially surround the top surface 132TS of the passive element 132 and/or lateral surfaces 132SS of the passive element 132. The resilient insulator 131 may include, for example, at least one material having elasticity or ductility. The resilient insulator 131 may include, for example, at least one epoxy molding compound (EMC). The resilient insulator 131 may include, for example, at least one thermoplastic polymer. A top surface 131TS of the resilient insulator 131 may be, for example, located at the same level as that of the top surface 100TS of the substrate 100, but example embodiments are not limited thereto.

The resilient insulator 131 may include an inner surface 131IS in contact with the passive element 132 and an outer surface 131OS in contact with the substrate 100. The inner surface 131IS of the resilient insulator 131 may be in contact with the lateral surface 132SS of the passive element 132. The outer surface 131OS of the resilient insulator 131 may be in contact with the substrate 100, but example embodiments are not limited thereto.

The resilient insulator 131 may surround the top surface 132TS of the passive element 132 and lateral surfaces 132SS of the passive element 132. A width in the first direction D1 of the resilient insulator 131 may be, for example, greater than a width in the first direction D1 of the passive element 132, but example embodiments are not limited thereto. The resilient insulator 131 may be interposed between the adhesive layer 210 and the top surface 132TS of the passive element 132.

The chip structure SST may be disposed on the substrate 100. The chip structure SST may include a first terminal 12 on the substrate 100, a first dielectric layer 202 that surrounds the first terminal 12, an interposer 203 on the first dielectric layer 202 and the first terminal 12, a second terminal 13 on the interposer 203, a semiconductor chip 201 on the second terminal 13, a logic chip 200 spaced apart from the semiconductor chip 201, and a molding layer 204 on the semiconductor chip 201 and the logic chip 200. A lateral surface of the chip structure SST may be exposed or at least partially exposed.

The first terminal 12 may be provided between and electrically connect the substrate 100 and the interposer 203. The first dielectric layer 202 may include a dielectric material. The first dielectric layer 202 may protect the first terminal 12 against outside. The second terminal 13 may be provided between the interposer 203 and each of the semiconductor chip 201 and the logic chip 200. The second terminal 13 may electrically connect the interposer 203 to each of the semiconductor chip 201 and the logic chip 200. The chip structure SST may include a plurality of semiconductor chips 201. For example, the logic chip 200 may be provided between the plurality of semiconductor chips 201, but example embodiments are not limited thereto.

The stiffening structure 301a may be provided on the substrate 100. The stiffening structure 301a may be attached through the adhesive layer 210 to the substrate 100. A width in the first direction D1 of the stiffening structure 301a may be greater than a width of the passive element structure 130, but example embodiments are not limited thereto.

The stiffening structure 301a may include a conductive material. The stiffening structure 301a may include a dielectric material and a conductive material. The stiffening structure 301a may overlap, for example overlap in the third direction, the passive element structure 130. The passive element structure 130 may not, for example, overlap the chip structure SST. The stiffening structure 301a may be spaced apart from the chip structure SST. A lateral surface of the stiffening structure 301a may be exposed or at least partially exposed.

The adhesive layer 210 may be interposed between the stiffening structure 301a and the passive element structure 130. The adhesive layer 210 may be in contact with the top surface 131TS of the resilient insulator 131. The adhesive layer 210 may include, for example, a conductive glue or a conductive tape, but example embodiments are not limited thereto. The adhesive layer 210 may overlap the passive element structure 130.

When the passive element structure 130 is mounted in the cavity CV of the substrate 100, a volume of the semiconductor package 1 may be reduced as much as a volume of the passive element structure 130.

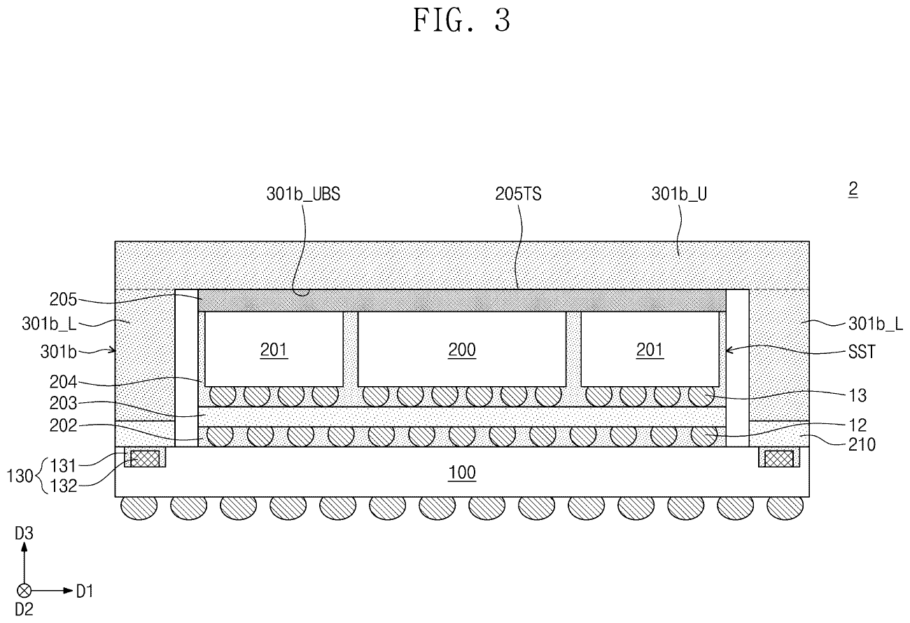

FIG. 3 illustrates a cross-sectional view showing a semiconductor package according to example embodiments of some inventive concepts. A duplicate description will be omitted below.

Referring to FIG. 3, a semiconductor package 2 may include an external terminal 11, a substrate 100 on the external terminal 11, a passive element structure 130 in the substrate 100, a chip structure SST on the substrate 100, a stiffening structure 301b on the substrate 100, and an adhesive layer 210 interposed between the stiffening structure 301b and the passive element structure 130.

The chip structure SST may include a first terminal 12 in contact with the substrate 100, an interposer 203 on the first terminal 12, a second terminal 13 on the interposer 203, a logic chip 200 on the second terminal 13, a semiconductor chip 201 on the second terminal 13, and an intervening conductive layer 205 on the logic chip 200.

The stiffening structure 301b may include a lower stiffener 301b_L and an upper stiffener 301b_U on the lower stiffener 301b_L. The upper stiffener 301b_U may be disposed on the chip structure SST. The upper stiffener 301b_U may have a plate or plate-like shape that extends in the first direction D1 and the second direction D2. The lower stiffener 301b_L may extend from the upper stiffener 301b_U toward the substrate 100.

The lower stiffener 301b_L and the chip structure SST may be spaced apart from each other. When the chip structure SST and the lower stiffener 301b_L are spaced apart from each other, an empty space may be between (for example, defined between or at least partially defined between) the chip structure SST and the lower stiffener 301b_L, but example embodiments are not limited thereto.

The stiffening structure 301b may include, for example, a material whose thermal conductivity is greater or substantially greater than that of the chip structure SST. The upper stiffener 301b_U may overlap the chip structure SST. The lower stiffener 301b_L may not overlap the chip structure SST.

The intervening conductive layer 205 may be interposed between the upper stiffener 301b_U and each of the semiconductor chip 201 and the logic chip 200. The intervening conductive layer 205 may include, for example, at least one a conductive material. The intervening conductive layer 205 may include, for example, a thermal interface material (TIM), but example embodiments are not limited thereto. The intervening conductive layer 205 may transfer heat to the upper stiffener 301b_U from the logic chip 200 and the semiconductor chip 201.

A top surface 205TS of the intervening conductive layer 205 may be in contact with a bottom surface 301b_UBS of the upper stiffener 301b_U. A width in the first direction D1 of the intervening conductive layer 205 may be less than a width in the first direction D1 of the upper stiffener 301b_U.

According to the present inventive concepts, as the passive element structure 130 is mounted in the substrate 100, a volume of the semiconductor package 1 may be reduced as much as a volume of the passive element structure 130, and as the upper stiffener 301b_U of the stiffening structure 301b is disposed on the chip structure SST, heat generated from the chip structure SST may be outwardly discharged.

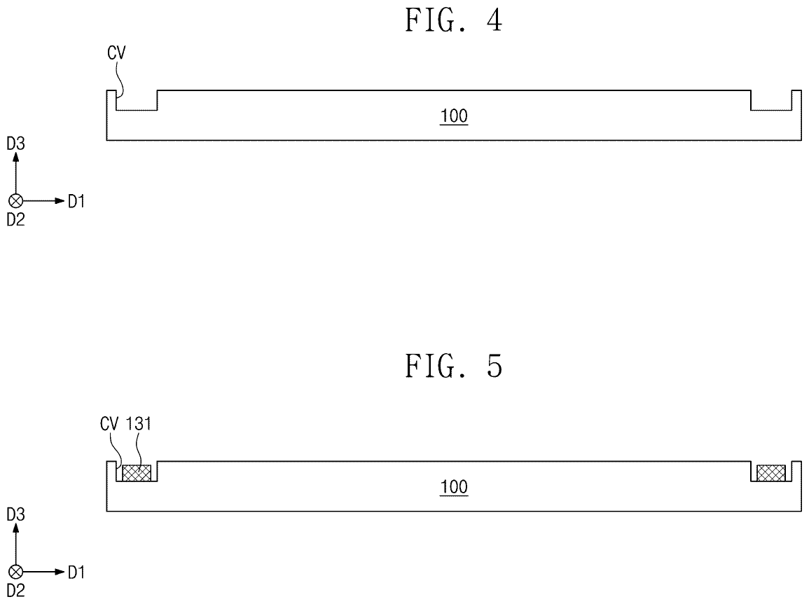

FIGS. 4, 5, and 6 illustrate cross-sectional views showing a method of fabricating a semiconductor package according to example embodiments of some inventive concepts.

Referring to FIG. 4, a substrate 100 may be provided which defines a cavity CV. The cavity CV may be provided as a plurality of cavities CV. The cavities CV may be formed spaced apart from each other on opposite sides of the substrate 100.

Referring to FIG. 5, a passive element 132 may be disposed in the cavity CV defined by the substrate 100. A width in the first direction D1 of the cavity CV defined by the substrate 100 may be less than a width in the first direction D1 of the passive element 132, and thus the lateral surfaces of the cavity CV and the passive element 132 may be spaced apart from each other.

A height of the cavity CV of the passive element 132 may be less than that of the passive element 132, and thus a top surface of the substrate 100 may be located at a lower level than that of a top surface of the passive element 132, but example embodiments are not limited thereto.

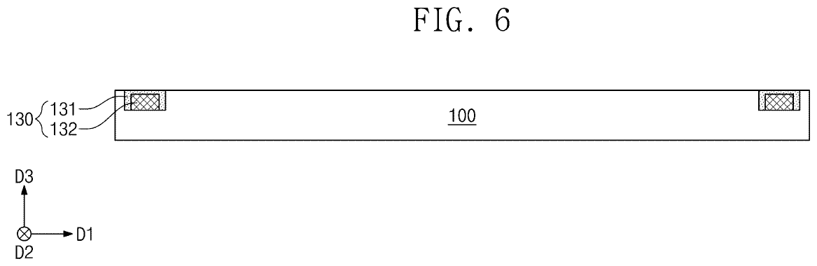

Referring to FIG. 6, a resilient insulator 131 may be formed on the passive element 132. The resilient insulator 131 may be formed to fill or at least partially fill a space between the passive element 132 and the cavity CV and to cover or at least partially cover the top surface of the passive element 132. The resilient insulator 131 may be formed, for example by coating a dielectric material on the passive element 132 and the cavity CV and performing a grinding process, but example embodiments are not limited thereto. As the resilient insulator 131 is formed, formation of a passive element structure 130 may be accomplished.

Referring back to FIG. 2, a chip structure SST and an adhesive layer 210 may be formed on the substrate 100, and a stiffening structure 301a may be formed on the adhesive layer 210.

In an example embodiment, the chip structure SST may be attached, and then the stiffening structure 301a may be attached through the adhesive layer 210, to the substrate 100.

In an example embodiment, the stiffening structure 301a may be attached through the adhesive layer 210 to the substrate 100, and then the chip structure SST may be attached to the substrate 100.

After the chip structure SST and the adhesive layer 210 are formed on the substrate 100, the stiffening structure 301a may be formed on the adhesive layer 210, and then external terminals 11 may be attached to a bottom surface of the substrate 100, but example embodiments are not limited thereto. As the external terminals 11 are attached, a semiconductor package 1 may be formed.

Referring back to FIG. 3, a chip structure SST and an adhesive layer 210 may be formed on the substrate 100, and then a stiffening structure 301b may be formed on the adhesive layer 210. The stiffening structure 301b may include, for example, a lower stiffener 301b_L and an upper stiffener 301b_U on the lower stiffener 301b_L. For example, the chip structure SST including an intervening conductive layer 205 may be attached to the substrate 100, and then the stiffening structure 301b may be attached through the adhesive layer 210 to the substrate 100, but example embodiments are not limited thereto. The stiffening structure 301b may be attached to allow the upper stiffener 301b_U to contact the intervening conductive layer 205.

After the chip structure SST and the adhesive layer 210 are formed on the substrate 100, the stiffening structure 301b may be formed on the adhesive layer 210, and then external terminals 11 may be attached to a bottom surface of the substrate 100, but example embodiments are not limited thereto. As the external terminals 11 are attached, a semiconductor package 2 may be formed.

According to the example embodiments of some inventive concepts, a passive element structure may be mounted in a substrate cavity, and thus a size of a semiconductor package may be reduced as much as a mounting area of the passive element structure.

According to the example embodiments of some inventive concepts, a passive element structure may include a passive element and a resilient insulator for protection of the passive element, and accordingly the passive element may be protected.

According to the example embodiments of some inventive concepts, a passive element may overlap a stiffening structure, and therefore a semiconductor package may become smaller in size, with the result that warpage risk may be reduced.

Although the example embodiments of some inventive concepts have been described in connection with the some example embodiments of inventive concepts illustrated in the accompanying drawings, it will be understood by one of ordinary skill in the art that variations in form and detail may be made therein without departing from the spirit and scope essential feature of inventive concepts. The above described example embodiments should thus be considered illustrative and not restrictive.

Although example embodiments of inventive concepts have been described with reference to the accompanying drawings, it will be apparent to those skilled in the art that inventive concepts may be realized in various forms without being limited to the above-described example embodiments and may be embodied in other specific forms without departing from the technical spirit and essential characteristics. Thus, the above example embodiments are to be considered in all respects as illustrative and neither limiting nor restrictive.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

What is claimed is:

1. A semiconductor package, comprising:
a substrate;
a chip structure on the substrate;
a passive element structure in the substrate and including a passive element; and
a stiffening structure at least partially overlapping the passive element structure,
wherein a top surface of the passive element is below a top surface of the substrate.

2. The semiconductor package of claim 1, wherein the passive element structure includes a resilient insulator, the resilient insulator at least partially surrounding the top surface of the passive element and a lateral surface of the passive element.

3. The semiconductor package of claim 2, wherein the resilient insulator has an inner surface and an outer surface,
the inner surface of the resilient insulator contacts the lateral surface of the passive element, and
the outer surface of the resilient insulator contacts the substrate.

4. The semiconductor package of claim 1, further comprising an adhesive layer between the stiffening structure and the passive element structure.

5. The semiconductor package of claim 1, wherein the stiffening structure includes an upper stiffener and a lower stiffener,
the upper stiffener is on the chip structure,
the lower stiffener extends from the upper stiffener toward the substrate, and
the lower stiffener and the chip structure are apart from each other.

6. The semiconductor package of claim 5, wherein the stiffening structure includes a material whose thermal conductivity is greater than a thermal conductivity of the chip structure.

7. The semiconductor package of claim 5, wherein the chip structure includes
a semiconductor chip;
a logic chip apart from the semiconductor chip; and
an intervening conductive layer on the semiconductor chip and the logic chip,
wherein a bottom surface of the upper stiffener contacts a top surface of the intervening conductive layer.

8. The semiconductor package of claim 1, wherein
the stiffening structure and the chip structure are apart from each other,
a lateral surface of the stiffening structure is at least partially exposed, and
a lateral surface of the chip structure is at least partially exposed.

9. The semiconductor package of claim 1, wherein the passive element structure does not overlap the chip structure.

10. A semiconductor package, comprising:
a substrate;
a chip structure on the substrate;
a passive element structure in the substrate, the passive element structure including a passive element and a resilient insulator on the passive element; and
a stiffening structure at least partially overlapping the passive element structure,
wherein the passive element structure is in a cavity defined by the substrate.

11. The semiconductor package of claim 10, wherein a top surface of the passive element is below a top surface of the substrate.

12. The semiconductor package of claim 10, wherein the passive element structure includes a resilient insulator, the resilient insulator at least partially surrounding a top surface of the passive element and a lateral surface of the passive element.

13. The semiconductor package of claim 10, further comprising:
an adhesive layer between the passive element structure and the stiffening structure,
wherein the resilient insulator is between the adhesive layer and a top surface of the passive element.

14. The semiconductor package of claim 10, wherein the stiffening structure includes
an upper stiffener; and
a lower stiffener extending from the upper stiffener toward the substrate,
wherein the upper stiffener at least partially overlaps the chip structure, and
the lower stiffener does not overlap the chip structure.

15. The semiconductor package of claim 14, wherein the chip structure includes
a first terminal contacting the substrate;
an interposer on the first terminal;
a second terminal on the interposer;
a logic chip on the second terminal; and
an intervening conductive layer on the logic chip,
wherein a top surface of the intervening conductive layer contacts a bottom surface of the upper stiffener.

16. The semiconductor package of claim 15, wherein
the chip structure and the lower stiffener are apart from each other, and
an empty space is between the chip structure and the lower stiffener.

17. The semiconductor package of claim 10, wherein a lateral surface and a top surface of the passive element contact the resilient insulator.

18. The semiconductor package of claim 12, wherein a top surface of the resilient insulator is coplanar with a top surface of the substrate.

19. A semiconductor package, comprising:
a substrate;
a chip structure on the substrate;
a passive element structure in a cavity defined by the substrate, wherein the passive element structure includes a passive element and a resilient insulator on the passive element; and
a stiffening structure at least partially overlapping the passive element structure,
wherein a top surface of the passive element is below a top surface of the substrate,
the top surface and a lateral surface of the passive element are contact the resilient insulator, and
an adhesive layer is between the stiffening structure and the passive element structure.

20. The semiconductor package of claim 19, wherein the stiffening structure includes
an upper stiffener; and
a lower stiffener extending from the upper stiffener toward the substrate,
wherein the upper stiffener at least partially overlaps the chip structure, and
the lower stiffener does not overlap the chip structure.
